(19) United States
(12) Patent Application Publication
(10) Pub. No.: US 2006/0228878 A1
(43) Pub. Date: Oct. 12, 2006

(54) Semiconductor package repair method

(75) Inventors: Chang-Yong Park, Cheonan-si (KR); Kyung-Du Kim, Daejeon-si (KR); Kwang-Ho Chun, Asan-si (KR); Byung-Man Kim, Cheonan-si (KR); Yong-Hyun Kim, Suwon-si (KR); Hyun-Jong Oh, Cheonan-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/387,801

(22) Filed: Mar. 24, 2006

(30) Foreign Application Priority Data
Apr. 6, 2005 (KR) 2005-28594

(51) Int. Cl. H01L 21/44

(52) U.S. Cl. 438/613

(57) ABSTRACT

A lower-melting-point solder having a lower melting point than solder balls is used to bond the solder balls with a module substrate. The lower-melting-point solder has a melting point lower than the solder balls. A bonding temperature is at a temperature between the melting point of the lower-melting-point solder and the melting point of the solder balls.

### CLAIM OF PRIORITY

A claim of priority under 35 U.S.C. §119 is made to Korean Patent Application No. 2005-28594, filed on Apr. 6, 2005; the entire contents of which are incorporated herein by reference.

### BACKGROUND

1. Field of the Invention

Example embodiments of the present invention generally relate to a semiconductor packaging. More particularly, example embodiments of the present invention relate to a package repair method using a lower-melting-point solder.

2. Description of the Related Art

Advancements in the multimedia and digital technologies have allowed electronic products to become smaller, lighter, faster, and/or more efficient. In addition, the electronic products operate at higher speeds with multiple functions. Accordingly, semiconductor products have advanced toward I/O pins having more pins and finer pitch. Ball grid array (BGA) packages using solder balls have been used to meet such advancements.

Semiconductor module products, for example a memory module, may include a module substrate and a plurality of semiconductor packages mounted on one or more surfaces of the module substrate. After packaging, the semiconductor module products may be tested. A specific package that is determined to be faulty during an electrical testing may be replaced with a replacement package. During a repair process, incomplete or excessive melting of solder balls may cause electrical connection problems. Further, heat used during the repair process may negatively influence solder balls of adjacent packages.

Methods of repairing and re-balling a BGA package have been suggested by the present inventors. When a replacement package is attached to a substrate, solder balls of the replacement package may be initially soldered with heat about 450° C. for about 20 seconds, and a final soldered may be performed by a reflow process with heat between about 220° C. and 230° C. for about 80 seconds. The reflow process allows uniform melting of the solder balls. Heat sinks may be used to cover adjacent packages to protect the solder balls from the heat. However, the method cannot be easily applied to a BGA stack package.

FIG. 1 illustrates an example of a BGA stack package.

Referring to FIG. 1, a plurality of BGA stack packages 12 may be mounted on two surfaces of a module substrate 10. Each of the BGA stack packages 12 may include a lower unit package 14a having first solder balls 16a, and an upper unit package 14b having second solder balls 16b. The BGA stack packages 12 may be attached to the module substrate 10 by the first solder balls 16a. The second solder balls 16b may connect the lower unit package 14a to the upper unit package 14b. Additional unit packages may be connected to each other.

If a single unit package is found to be faulty, the entire stack package 12 including the faulty unit package may be replaced with a replacement stack package. Heat may be applied to the stack package 12 to separate it from the module substrate 10. Heat sinks may be used to cover adjacent stack packages 12 to protect them from the heat. However, the heat sink may not completely resolve the solder ball problems. For example, when a replacement stack package 15 is attached to the module substrate 10, it may be advantageous to apply heat to only the first solder balls 16a of the lower unit package 14a. However, a specific targeted heat application may not be feasible. In practice, heat is applied to the entire replacement stack package 15. As a result, heat may be applied to the second solder balls 16b. As a result, faults 18a and 18b may occur to the second solder balls 16b as shown in FIG. 2.

### SUMMARY OF THE INVENTION

In an embodiment of the present invention, a method of bonding a ball grid array (BGA) package includes providing a lower-melting-point solder on solder balls of the BGA package, and bonding the lower-melting-point solder on the solder balls to a module substrate at a temperature between the melting point of the lower-melting-point solder and the melting point of the solder balls, wherein the lower-melting-point solder has a melting point lower than the solder balls.

In another embodiment of the present invention, a method of repairing a ball grid array (BGA) package, includes removing a defective BGA package from a module substrate, providing a lower-melting-point solder on solder balls of a replacement BGA package, and bonding the lower-melting-point solder on the solder balls to the module substrate at a temperature between the melting point of the lower-melting-point solder and the melting point of the solder balls, wherein the lower-melting-point solder has a melting-point lower than the solder balls.

### BRIEF DESCRIPTION OF THE DRAWINGS

The embodiments of the present invention will be better understood with reference to the following detailed description thereof provided in conjunction with the accompanying drawings.

FIG. 1 is a cross-sectional view illustrating a conventional BGA package.

FIG. 2 is a cross-sectional view illustrating solder ball faults of the conventional BGA stack package.

FIGS. 3A through 3D are cross-sectional views illustrating a package repairing method according to an example embodiment of the present invention.

FIGS. 4A through 4C are cross-sectional views illustrating a package repair method accordingly to another example embodiment of the present invention.

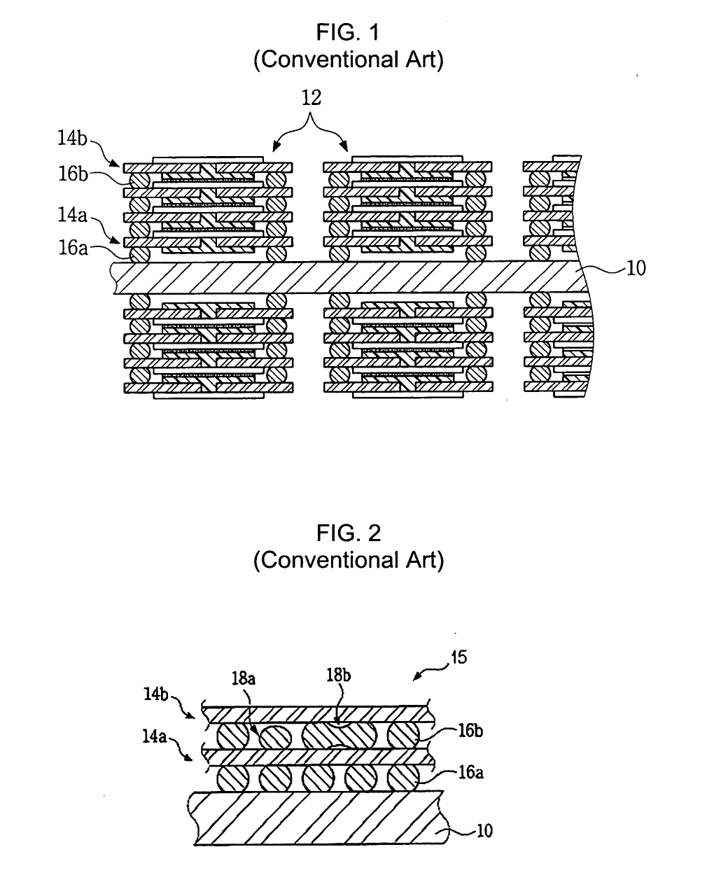

### DETAILED DESCRIPTION OF THE EXAMPLE EMBODIMENTS

Example embodiments of the present invention will now be described more fully hereinafter with reference to the accompanying drawings. The drawings are provided for illustrative purposes only and are not drawn to scale. The spatial relationships and relative sizing of the elements illustrated in the various embodiments may be reduced, expanded or rearranged to improve the clarity of the figures with respect to the corresponding description. The figures, therefore, should not be interpreted as accurately reflecting the relative sizing or positioning of the corresponding structural elements that could be encompassed by an actual device manufactured according to the example embodiments of the invention.

The present invention may be embodied in many different forms and should not be construed as limited to the example embodiments set forth herein. Rather, the disclosed embodiments are provided as working examples. Aspects of this invention may be employed in varied and numerous embodiments without departing from the scope of the invention.

Further, well-known structures and processes are not described or illustrated in detail to avoid obscuring the present invention. Like reference numerals are used for like and corresponding parts of the various drawings.

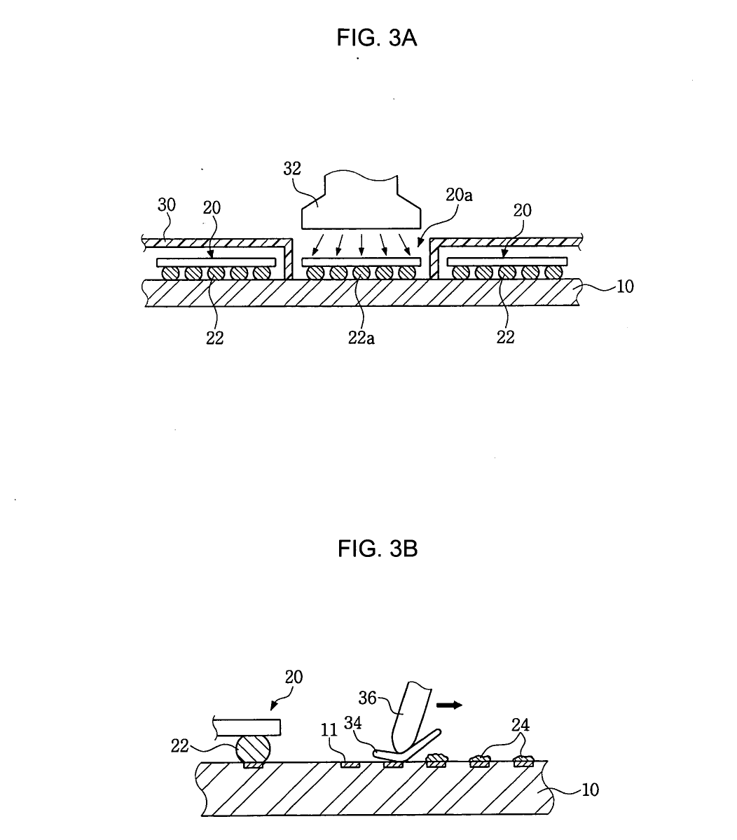

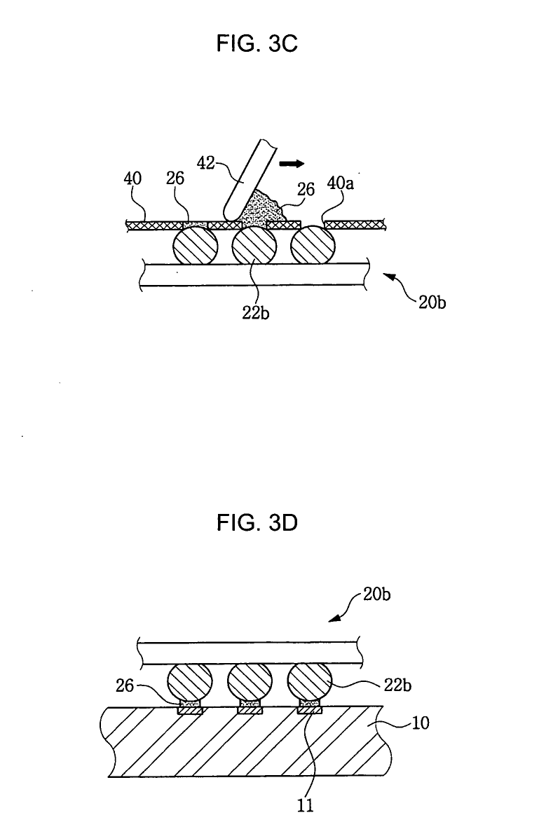

FIGS. 3A through 3D are cross-sectional views illustrating a package repairing method according to an example embodiment of the present invention.

Referring to FIG. 3A, a plurality of BGA packages 20 and 20a may be mounted on a module substrate 10. The BGA packages 20 and 20a may include various types of package according to their configuration, but they are commonly mounted on a module substrate using solder balls. The detailed description of other elements of the BGA packages 20 and 20a are herein omitted. Although this embodiment shows the BGA packages 20 and 20a mounted on one surface of the module substrate 10, the BGA packages 20 and 20a may be mounted on two or more surfaces of the module substrate 10.

For illustrative purposes, it is assumed that after an electrical test process, the BGA package 20a is determined to be faulty. The BGA package 20a may be replaced with a replacement package through a repair process. First, heat may be applied to the faulty package 20a to separate it from the module substrate 10.

Heat sinks 30 may be used to cover and protect adjacent packages 20 from the heat. The heat may be applied to the BGA package 20a using a heating apparatus 32. The heating apparatus 32 may eject nitrogen gas at about 450° C. for about 60 seconds.

The solder balls 22a of the BGA package 20a are melted by the heating apparatus 32, and the BGA package 20a is separated from the module substrate 10. The heating apparatus 32 may have a vacuum suction unit to remove the BGA package 20a by vacuum suction.

Referring to FIG. 3B, solder residue 24 on the surface of the module substrate 10 may be removed. The solder residue 24 is a solder material, which may remain on substrate pads 11 after the solder balls 22a have been removed. A solder wicker 34 may be placed on the module substrate 10 and pressed on the solder residue 24 using an iron 36.

Referring to FIG. 3C, a compound of solder powder and a flux of liquid or paste, e.g., a lower-melting-point solder 26, may be provided on replacement solder balls 22b of a replacement package 20b. The lower-melting-point solder 26 has a melting point lower than the replacement solder balls 22b.

Formation of the lower-melting-point solder 26 may include placing a stencil 40 on the replacement solder balls 22b. The stencil 40 may have openings 40a formed corresponding to the locations of the replacement solder balls 22b. The diameter of the opening 40a is usually smaller than that of the replacement solder ball 22b so that the stencil 40 can be placed on the replacement solder balls 22b. For example, the diameter of the opening 40a may be about 0.4 mm and the diameter of the replacement solder ball 22b may be about 0.5 mm. Also, the thickness of the stencil 40 may be about 0.15 mm.

The lower-melting-point solder 26 may be provided on the stencil 40 and applied into the openings 40a with a squeeze 42. Thereby, the lower-melting-point solder 26 may be printed on the replacement solder balls 22b.

As described above, the lower-melting-point solder 26 may be formed of materials having a lower melting point than the replacement solder balls 22b. The replacement solder balls 22b and the low-melting point solder 26 may be formed from Sn/Pb, Sn/Ag/Cu, Sn/Ag, Sn/Cu, Sn/Bi, Sn/Zn/Bi, Sn/Ag/Bi, Sn/Ag/Zn, In/Sn, WAg, Sn/Pb/Ag, In/Pb, Sn, Sn/Pb/Bi, or Sn/Pb/Bi/Ag.

Although the solder materials may be the same for the replacement solder balls 22b and the lower-melting-point solder 26, they have different melting points from each other by adjusting their compositions and distribution ratio. The replacement solder balls 22b and the lower-melting-point solder 26 may be formed by suitably selecting from the solder materials. For example, the replacement solder balls 22b may be formed of Sn/Ag/Cu having a distribution ratio of 96.5/3/0.5 and a melting point of 217° C., and the lower-melting-point solder 26 may be formed of Sn/Pb having a distribution ratio of 63/37 and a melting point of 183° C. In other embodiments, the replacement solder balls 22b and/or the lower-melting-point solder 26 may be formed from Sn/Ag having a distribution ratio of 96.5/3.5 and a melting point of 221° C.; Sn/Cu having a distribution ratio of 99.3/0.7 and a melting point of 235° C.; Sn/Bi having a distribution ratio of 43/57 and a melting point of 139° C.; and, Sn/Zn/Bi having a distribution ratio of 89/3/8 and a melting point of 187° C.

Referring to FIG. 3D, a replacement package 20b may be attached to the module substrate 10. The replacement solder balls 22b of the replacement package 20b may be connected to the substrate pads 11 of the module substrate 10 with the lower-melting-point solder 26. After the solder reflow process, the replacement solder balls 22b may be completely joined with the substrate pads 11. The process conditions of the solder reflow process may be set in accordance with the materials of the replacement solder balls 22b and the lower-melting-point solder 26.

Table 1 illustrates example process conditions of the solder reflow process. Here, the solder balls 22b is formed of Sn/Ag/Cu having a distribution ratio of 96.5/3/0.5, and the lower-melting-point solder 26 is formed of Sn/Pb having a distribution ratio of 63/37.

TABLE 1

| Preheating | | | | |
|---|---|---|---|---|
| | Gradient | Stabilization | | Peak Temperature |
| Temperature(□) | (° C./Sec) | Temperature(° C.) | Time(Sec) | Temperature(° C.) |

| | | | | |
|---|---|---|---|---|
| 140-160 | 1.6-2.5 | 155-175 | 60-100 | 210-230 |

In a solder reflow process under the process conditions of Table 1, although the peak temperature may be set between about 210° C. and 230° C., temperature applied to the solder balls 22b and the lower-melting-point solder 26 may, in practice, range between about 183-217° C., e.g., the melting point of Sn/Pb and the melting point of Sn/Ag/Cu, respectively. As a result, the replacement solder balls 22b do not melt, but the lower-melting-point solder 26 melts. Therefore, a solder reflow process may be set to a temperature between the melting point of the solder balls 22b and the melting point of the lower-melting-point solder 26.

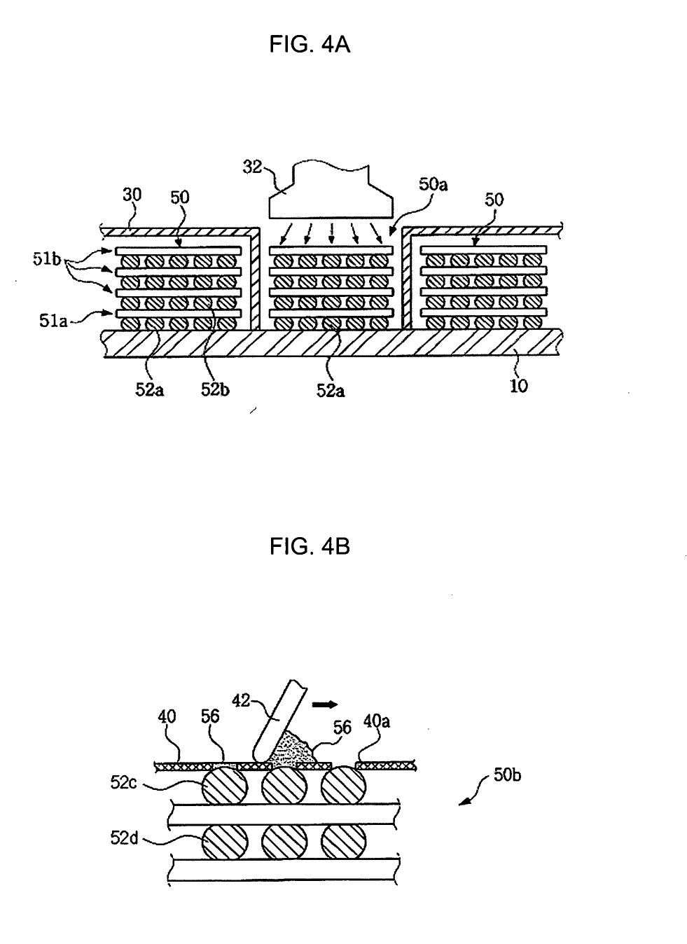

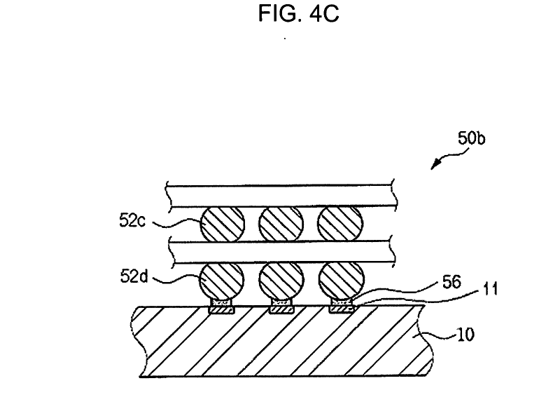

FIGS. 4A through 4C are cross-sectional views illustrating a package repair method accordingly to another example embodiment of the present invention.

Referring to FIG. 4A, a plurality of BGA stack packages 50 and 50a are preferably mounted on a surface of a module substrate 10. In another embodiment, the BGA stack packages 50 and 50a may be mounted on two surfaces of the module substrate 10. Each of the BGA stack packages 50 and 50a may include a lower unit package 51a having first solder balls 52a, and an upper unit package 51b having second solder balls 52b. Although an example embodiment may show four unit packages included in a single stack package, the number of the unit packages may be varied. The BGA stack packages 50 and 50a may be connected to the module substrate 10 by the first solder balls 52a. The second solder balls 52b may connect the lower unit package 51a to the upper unit package 51b, the upper unit package 51b may be connected to another unit package depending on the number of unit packages.

For illustrative purposes, it is assumed that after an electrical test process, a specific unit package has been determined to be faulty, wherein the entire stack package 50a including the faulty unit package may be replaced with a replacement stack package 50b by a repair process. First, heat may be applied to the stack package 50a to separate it from the module substrate 10. This heating may be performed in substantially the same manner as that illustrated in FIG. 3A, e.g., heat sinks 30 and a heating apparatus 32 may also be used. The detailed description of the heating step is therefore omitted. Subsequently, solder residue on the surface of the module substrate 10 may be removed.

Referring to FIG. 4B, lower-melting-point solder 56 may be formed on a first replacement solder balls 52c. The lower-melting-point solder 56 may be formed using a printing method, in the same manner as illustrated in FIG. 3C. The first replacement solder balls 52c and a replacement second solder balls 52d may be formed of the same materials. The lower-melting-point solder 56 may be formed of materials having a lower melting point than materials of the first and second replacement solder balls 52c and 52d. Example solder materials of the first and second solder replacement balls 52c and 52d and the lower-melting-point solder 56 may be the same as in the above example embodiment shown in FIGS. 3A-3D.

Referring to FIG. 4C, the replacement stack package 50b may be attached to the module substrate 10. The first replacement solder balls 52c may be connected to substrate pads 11 of the module substrate 10 using the lower-melting-point solder 56. After a solder reflow process, the first replacement solder balls 52c may be completely joined with substrate pads 11. The process condition of the solder reflow process may be set according to the materials of the first and second replacement solder balls 52c and 52d and the lower-melting-point solder 56 to ensure that the lower-melting-point solder 56 melt during the solder reflow process.

During the solder reflow process, heat applied to the first and replacement second solder balls 52c and 52d and the lower-melting-point solder 56 may range between the melting points of the first and second replacement solder balls 52c and 52d and the melting point of the lower-melting-point solder 56. Thereby, the second replacement solder balls 52b are less susceptible to faults caused by heat used in the solder reflow process.

A soldering method in accordance with the example embodiments of the present invention may be characterized by use of a lower-melting-point solder. For example, a lower-melting-point solder may be implemented in mounting BGA packages on a module substrate. The use of lower-melting-point solder may lead to improved package repairs.

The temperature cycle (TC) test may be a reliability test for packages, which tests solder joint reliability at a variety of temperatures between −25° C. and 125° C. The temperature cycle may last about 30 minutes, and may include temperature maintenance at −25° C. for about 10 minutes, a temperature rise for about 5 minutes, a temperature maintenance at 125° C. for about 10 minutes, and a temperature decline for about 5 minutes.

The conventional BGA package using solder balls formed of Sn/Ag/Cu having a distribution ratio of 96.5/3/0.5 has a reliability of TC1000. In other words, reliability is maintained during 1000 temperature cycles. A BGA package of example embodiments of the present invention formed of Sn/Pb having a distribution ratio of 63/37 has reliability between TC1500 and TC2000. That is, reliability may be maintained between 1500 and 2000 temperature cycles.

Although non-limiting embodiments of the present invention have been described in detail hereinabove, it should be understood that many variations and/or modifications of the basic inventive concepts herein taught, which may appear to those skilled in the art, will still fall within the scope of the example embodiments of the present invention.

What is claimed is:

1. A method of bonding a ball grid array (BGA) package, comprising:
providing a lower-melting-point solder on solder balls of the BGA package; and
bonding the lower-melting-point solder on the solder balls to a module substrate at a temperature between the melting point of the lower-melting-point solder and the melting point of the solder balls,
wherein the lower-melting-point solder has a melting point lower than the solder balls.

2. The method of claim 1, wherein the solder balls and the lower-melting point solder are each selected from solder materials consisting of Sn/Pb, Sn/Ag/Cu, Sn/Ag, Sn/Cu, Sn/Bi, Sn/Zn/Bi, Sn/Ag/Bi, Sn/Ag/Zn, In/Sn, In/Ag, Sn/Pb/Ag, In/Pb, Sn, Sn/Pb/Bi, and Sn/Pb/Bi/Ag.

3. The method of claim 2, wherein the solder balls are formed of Sn/Ag/Cu having a distribution ratio of 96.5/3/0.5 and a melting point of about 217° C., and the lower-melting-point solder is formed of Sn/Pb having a distribution ratio of 63/37 and a melting point of about 183° C.

4. The method of claim 1, wherein providing the lower-melting-point solder includes placing a stencil on the solder balls, the stencil having openings formed corresponding to locations of the solder balls, providing the lower-melting-point solder on the stencil, and applying the lower-melting-point solder into the openings.

5. The method of claim 4, wherein a diameter of the opening is smaller than a diameter of the solder balls.

6. The method of claim 1, wherein the bonding of the lower-melting-point solder to the module substrate is a solder reflow process including preheating and stabilizing.

7. The method of claim 3, wherein the bonding of the lower-melting-point solder to the module substrate is a solder reflow process including preheating and stabilizing, and wherein a peak temperature is between about 210° C. and 230° C.

8. The method of claim 7, wherein a preheating temperature is between about 140° C. and 160° C. and a preheating gradient is between about 1.6/sec and 2.5/sec, and a stabilization temperature is between about 155° C. and 175° C. and a stabilization time is between about 60 seconds and 100 seconds.

9. The method of claim 1, wherein the BGA package is a BGA stack package.

10. The method of claim 1, wherein the lower-point-melting solder of the solder balls are bonded to substrate pads on the module substrate.

11. A method of repairing a ball grid array (BGA) package, comprising:
removing a defective BGA package from a module substrate;
providing a lower-melting-point solder on solder balls of a replacement BGA package; and
bonding the lower-melting-point solder on the solder balls to the module substrate at a temperature between the melting point of the lower-melting-point solder and the melting point of the solder balls,
wherein the lower-melting-point solder has a melting point lower than the solder balls.

12. The method of claim 11, wherein the solder balls and the lower-melting point solder are each selected from solder materials consisting of Sn/Pb, Sn/Ag/Cu, Sn/Ag, Sn/Cu, Sn/Bi, Sn/Zn/Bi, Sn/Ag/Bi, Sn/Ag/Zn, In/Sn, In/Ag, Sn/Pb/Ag, In/Pb, Sn, Sn/Pb/Bi, and Sn/Pb/Bi/Ag.

13. The method of claim 12, wherein the solder balls are formed of Sn/Ag/Cu having a distribution ratio of 96.5/3/0.5 and a melting point of 217° C., and the lower-melting-point solder is formed of Sn/Pb having a distribution ratio of 63/37 and a melting point of 183° C.

14. The method of claim 11, wherein forming the lower-melting-point solder includes placing a stencil on the solder balls, the stencil having openings formed corresponding to locations of the solder balls, providing the lower-melting-point solder on the stencil, and applying the lower-melting-point solder into the openings.

15. The method of claim 14, wherein a diameter of the opening is smaller than a diameter of the solder balls.

16. The method of claim 11, wherein the bonding of the lower-melting-point solder to the module substrate is a solder reflow process including a preheating step and a stabilization step.

17. The method of claim 13, wherein the bonding of the lower-melting-point solder to the module substrate is a solder reflow process including a preheating step and a stabilization step, and wherein a peak temperature is between about 210° C. and 230° C.

18. The method of claim 17, wherein a preheating temperature is between about 140° C. and 160° C. and a preheating gradient is between about 1.6/sec and 2.5/sec, and a stabilization temperature is between about 155° C. and 175° C. and a stabilization time is between about 60 seconds and 100 seconds.

19. The method of claim 11, wherein the BGA package is a BGA stack package.

20. The method of claim 11, wherein the lower-point-melting solder of the solder balls are bonded to substrate pads on the module substrate.
